(19) United States
(12) Patent Application Publication
(10) Pub. No.: US 2025/0029644 A1
(43) Pub. Date: Jan. 23, 2025

(54) MAGNETIC MEMORY DEVICE

(71) Applicant: Samsung Electronics Co., Ltd., Suwon-si, Gyeonggi-do (KR)

(72) Inventors: Unghwan Pi, Suwon-si (KR); Stuart Papworth Parkin, Munchen (DE); Jaechun Jeon, Munchen (DE); Jaekeun Kim, Munchen (DE); Andrea Migliorini, Munchen (DE)

(73) Assignee: Max-Planck-Gesellschaft zur Forderung der Wissenschaften e.V., Munchen (DE)

(21) Appl. No.: 18/773,949

(22) Filed: Jul. 16, 2024

(30) Foreign Application Priority Data
Jul. 18, 2023 (KR) 10-2023-0093343

(51) Int. Cl. G11C 11/16; G11C 11/18; G11C 19/08; H01F 10/32; H10B 61/00; H10N 50/10; H10N 50/80

(52) U.S. Cl. CPC G11C 11/161; G11C 11/1673; G11C 11/18; G11C 19/0841; H01F 10/3254; H10B 61/00; H10N 50/10; H10N 50/80

(57) ABSTRACT

A magnetic memory device includes a lower magnetic track layer extending in a first direction and including a plurality of first magnetic domains, a spacer layer on the lower magnetic track layer and extending in the first direction, an upper magnetic track layer on the spacer layer and extending in the first direction, the upper magnetic track layer including a plurality of second magnetic domains, and a plurality of read units on the upper magnetic track layer and arranged apart from one another in the first direction, wherein the plurality of first magnetic domains and the plurality of second magnetic domains have magnetization directions parallel to each other at positions overlapping each other in a second direction perpendicular to the first direction.

### CROSS-REFERENCE TO RELATED APPLICATION

This application is based on and claims priority under 35 U.S.C. § 119 to Korean Patent Application No. 10-2023-0093343, filed on Jul. 18, 2023, in the Korean Intellectual Property Office, the disclosure of which is incorporated by reference herein in its entirety.

### BACKGROUND

The inventive concept relates to a magnetic memory device, and more particularly, to a magnetic memory device including a racetrack.

High-capacity memory devices are used for miniaturized, multifunctional, and high-performance electronic products. A racetrack, including a plurality of magnetic domains storing information according to the motion of a domain wall between magnetic domains, has been proposed for providing a high capacity memory device. Also, memory devices of a magnetic domain wall shift register type including a racetrack have been developed. it is generally desirable to implement magnetic memory devices with a stable motion of a magnetic domain wall, a high degree of integration, and desired long lifetime.

### SUMMARY

The inventive concept provides a magnetic memory device in which a high degree of integration is implemented with a racetrack, which may reduce damage to a tunnel barrier in a magnetic tunnel junction structure.

The object of the inventive concept is not limited to the aforesaid, but other objects not described herein will be clearly understood by those of ordinary skill in the art from descriptions below.

According to an aspect of the inventive concept, there is provided a magnetic memory device including a lower magnetic track layer extending in a first direction and including a plurality of first magnetic domains, a spacer layer on the lower magnetic track layer and extending in the first direction, an upper magnetic track layer on the spacer layer and extending in the first direction, the upper magnetic track layer including a plurality of second magnetic domains, and a plurality of read units on the upper magnetic track layer and arranged apart from one another in the first direction, wherein the plurality of first magnetic domains and the plurality of second magnetic domains have magnetization directions parallel to each other at positions overlapping each other in a second direction perpendicular to the first direction.

According to another aspect of the inventive concept, there is provided a magnetic memory device including a spin hall conductive layer, an operation magnetic track layer and a copy magnetic track layer, stacked in a first direction on the spin hall conductive layer, a spacer layer between the operation magnetic track layer and the copy magnetic track layer, a tunnel barrier layer on the copy magnetic track layer, and a plurality of magnetic tunnel junction sensors on the tunnel barrier layer, wherein the operation magnetic track layer and the copy magnetic track layer have magnetization directions parallel to each other at positions overlapping each other in the first direction, based on a leakage magnetic field of the operation magnetic track layer.

According to another aspect of the inventive concept, there is provided a magnetic memory device including a lower magnetic track layer including a plurality of first magnetic domains and a plurality of first magnetic domain walls alternately arranged and extending in a first direction, a spacer layer on the lower magnetic track layer and extending in the first direction, the spacer layer having a thickness of about 1 nm to about 5 nm, an upper magnetic track layer including a plurality of second magnetic domains and a plurality of second magnetic domain walls alternately arranged and extending in the first direction, the upper magnetic track layer being on the spacer layer, and a plurality of read units on the upper magnetic track layer, the plurality of read units being configured to read a magnetization direction of the upper magnetic track layer and being arranged apart from one another in the first direction, wherein the plurality of first magnetic domain walls and the plurality of second magnetic domain walls overlap each other in a second direction perpendicular to the first direction, and wherein the plurality of first magnetic domains and the plurality of second magnetic domains have magnetization directions parallel to each other at positions overlapping each other in the second direction.

### BRIEF DESCRIPTION OF THE DRAWINGS

Embodiments will be more clearly understood from the following detailed description taken in conjunction with the accompanying drawings in which:

FIG. 1 is a cross-sectional view illustrating elements of a magnetic memory device according to some embodiments;

FIG. 2 is a cross-sectional view illustrating an initial state (or a first state) of the magnetic memory device of FIG. 1 according to some embodiments;

FIG. 3 is a cross-sectional view illustrating a final state (or a second state) of the magnetic memory device of FIG. 1 according to some embodiments;

FIGS. 4 and 5 are cross-sectional views illustrating main elements of a magnetic memory device according to further embodiments;

FIG. 6 is a flowchart illustrating a method of manufacturing a magnetic memory device, according to some embodiments;

FIGS. 7 to 9 are cross-sectional views illustrating a method of manufacturing a magnetic memory device in process sequence, according to some embodiments; and

FIGS. 10A to 10C are diagrams illustrating a magnetic copy feature of a magnetic memory device according to some embodiments.

### DETAILED DESCRIPTION OF THE EMBODIMENTS

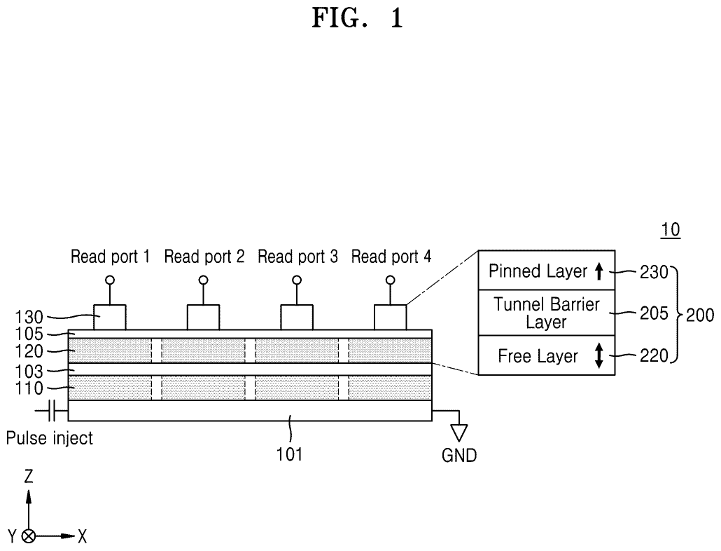

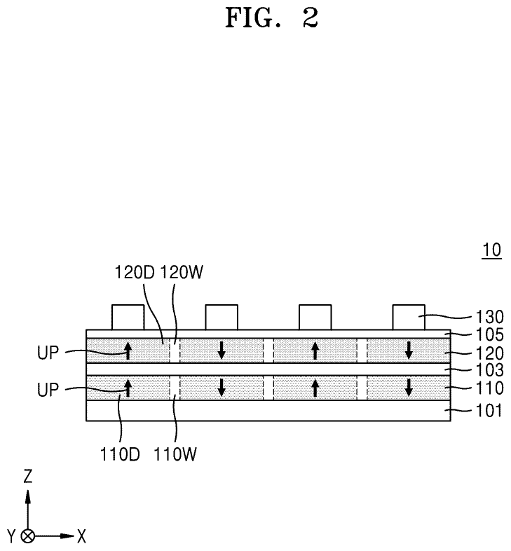

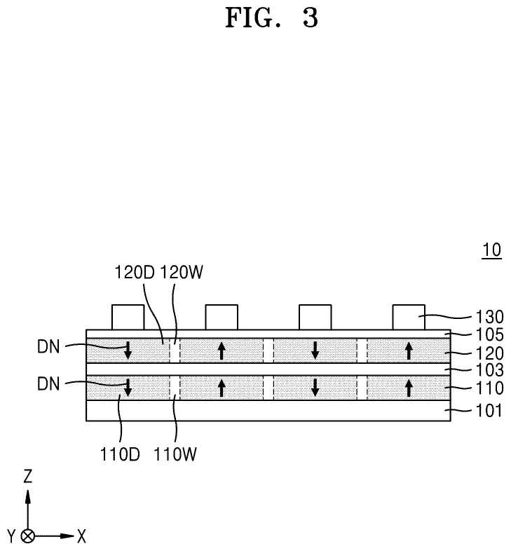

Hereinafter, embodiments will be described in detail with reference to the accompanying drawings. Like reference numerals in the drawings denote like elements, and thus their description will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. FIG. 1 is a cross-sectional view illustrating elements of a magnetic memory device 10 according to some embodiments, FIG. 2 is a cross-sectional view illustrating an initial state (or a first state) of the magnetic memory device 10 of FIG. 1 according to some embodiments, and FIG. 3 is a cross-sectional view illustrating a final state (or a second state) of the magnetic memory device 10 of FIG. 1 according to some embodiments.

Referring to FIGS. 1 to 3, the magnetic memory device 10 according to an embodiment may include a conductive layer 101, a lower magnetic track layer 110 disposed on the conductive layer 101, a spacer layer 103 disposed on the lower magnetic track layer 110, an upper magnetic track layer 120 disposed on the spacer layer 103, a tunnel barrier layer 105 disposed on the upper magnetic track layer 120, and a plurality of read units 130 disposed on the tunnel barrier layer 105.

In some embodiments, the conductive layer 101 may include an induction layer, which allows a spin orbit torque (SOT) to be generated with a current flowing in the conductive layer 101. In other embodiments, the conductive layer 101 may include a material, which allows a spin hall effect or Rashba effect to be implemented with a current which flows in a first horizontal direction X or a direction opposite to the first horizontal direction X in the conductive layer 101. In other words, the conductive layer 101 may be referred to as a spin hall conductive layer. Also, a pulse injection unit and a ground (GND) unit may be connected to the conductive layer 101.

Also, the conductive layer 101 may include a heavy metal where an atomic number is 30 or more. For example, the conductive layer 101 may include iridium (Ir), ruthenium (Ru), tantalum (Ta), platinum (Pt), palladium (Pd), bismuth (Bi), titanium (Ti), and/or tungsten (W), but embodiments are not limited thereto.

The magnetic memory device 10 according to an embodiment may include the lower magnetic track layer 110, the spacer layer 103, and the upper magnetic track layer 120, which are sequentially stacked on the conductive layer 101. The lower magnetic track layer 110, the spacer layer 103, and the upper magnetic track layer 120 may be stacked on the conductive layer 101 in a vertical direction Z. Here, the lower magnetic track layer 110 may be disposed between the conductive layer 101 and the spacer layer 103, and the spacer layer 103 may be disposed between the lower magnetic track layer 110 and the upper magnetic track layer 120. In some embodiments, a length of the conductive layer 101, a length of the lower magnetic track layer 110, a length of the spacer layer 103, and a length of the upper magnetic track layer 120 may be equal to one another in the first horizontal direction X.

In some embodiments, the lower magnetic track layer 110, the spacer layer 103, and the upper magnetic track layer 120 may have a line shape having a straight-line shape, which extends long in a first horizontal direction X and has a certain width in a second horizontal direction Y perpendicular to the first horizontal direction X. In other embodiments, the lower magnetic track layer 110, the spacer layer 103, and the upper magnetic track layer 120 may have a line shape having a U-shape.

The lower magnetic track layer 110 may include first magnetic domains 110D and first magnetic domain walls 110W each provided between two adjacent first magnetic domains 110D of the first magnetic domains 110D, which are arranged in the first horizontal direction X. The first magnetic domain 110D may be a region where a magnetic moment is aligned in a certain direction in the lower magnetic track layer 110. Also, the first magnetic domain wall 110W may be a region where a direction of a magnetic moment is changed between the first magnetic domains 110D. The first magnetic domains 110D and the first magnetic domain walls 110W may be alternately arranged in the first horizontal direction X.

The upper magnetic track layer 120 may include second magnetic domains 120D and second magnetic domain walls 120W each provided between two adjacent second magnetic domains 120D of the second magnetic domains 120D, which are arranged in the first horizontal direction X. The second magnetic domain 120D may be a region where a magnetic moment is aligned in a certain direction in the upper magnetic track layer 120. Also, the second magnetic domain wall 120W may be a region where a direction of a magnetic moment is changed between the second magnetic domains 120D. The second magnetic domains 120D and the second magnetic domain walls 120W may be alternately arranged in the first horizontal direction X.

In some embodiments, the second magnetic domain 120D may overlap each of the first magnetic domains 110D in a vertical direction Z. Also, as will be described below, magnetization directions of the first magnetic domains 110D and the second magnetic domain 120D overlapping each other in the vertical direction Z may be parallel to each other. The first magnetic domain walls 110W and the second magnetic domain walls 120W may overlap each other in the vertical direction Z.

The upper magnetic track layer 120 may substantially accurately copy a magnetization direction of the lower magnetic track layer 110 through the spacer layer 103 based on a leakage magnetic field, and thus, a magnetization direction may be set. In other words, the lower magnetic track layer 110 may be referred to as an operation magnetic track layer, and the upper magnetic track layer 120 may be referred to as a copy magnetic track layer or a link magnetic track layer. In other embodiments, based on a stack order, the lower magnetic track layer 110 may be referred to as a first magnetic track layer, and the upper magnetic track layer 120 may be referred to as a second magnetic track layer.

In the initial state (or the first state) of the magnetic memory device 10, a magnetization direction of a leftmost first magnetic domain 110D of the lower magnetic track layer 110 may be an upside UP, and thus, a magnetization direction of a corresponding second magnetic domain 120D of the upper magnetic track layer 120 may be an upside UP in parallel.

In the final state (or the second state) of the magnetic memory device 10, the magnetization direction of the leftmost first magnetic domain 110D of the lower magnetic track layer 110 may be changed to a downside DN, and thus, the magnetization direction of the corresponding second magnetic domain 120D of the upper magnetic track layer 120 may be changed to a downside DN in parallel.

Each of the lower magnetic track layer 110 and the upper magnetic track layer 120 may include a magnetic element, and for example, may include one or more of cobalt (Co), iron (Fe), and nickel (Ni). However, a magnetic element included in the lower magnetic track layer 110 may differ from a magnetic element included in the upper magnetic track layer 120. For example, the lower magnetic track layer 110 may include Co and Ni and may not include Fe, and the upper magnetic track layer 120 may include Co and Fe and may not include Ni.

The spacer layer 103 may include an insulating material, and for example, may include one or more of hexagonal boron nitride (h-BN), aluminum oxide, silicon oxide, silicon nitride, silicon oxynitride, and graphene.

In detail, boron nitride may be a compound where boron (B) and nitrogen (N) are mixed at the same ratio and may have a crystal form of hexagonal, cubic, and/or wurtzite. Here, h-BN may be a material, which is high in thermal conductance, good in chemical stability, robust to a thermal impact, and excellent in mechanical strength. Also, h-BN may include a single-layer structure material (i.e., a two-dimensional sheet structure) including a boron (B) atom and a nitrogen (N) atom each having a hexagonal lattice structure. In this context, h-BN may have a feature similar to graphene including a carbon (C) atom having a hexagonal lattice structure. As will be described below, a method of manufacturing the magnetic memory device 10 according to an embodiment will be described based on a feature of h-BN.

In some embodiments, a thickness of the spacer layer 103 may have a range of about 1 nm to about 5 nm. As will be described below, when a thickness of the spacer layer 103 is about 1 nm to about 5 nm, a magnetization direction of the lower magnetic track layer 110 may be copied to be substantially equal to a magnetization direction of the upper magnetic track layer 120. On the other hand, when a thickness of the spacer layer 103 is greater than about 5 nm, a difference between the magnetization direction of the lower magnetic track layer 110 and the magnetization direction of the upper magnetic track layer 120 may result. Also, it may be difficult to form a thickness of the spacer layer 103 to a thickness that is less than about 1 nm, and it may be difficult to implement a magnetic characteristic with respect to a fine thickness.

The lower magnetic track layer 110 may include a synthetic anti-ferromagnetism (SAF) property and/or a synthetic ferromagnetism (SF) property. The SAF and/or the SF may each be in a region where magnetic layers (not shown) included in the lower magnetic track layer 110 and coupling layers (not shown) disposed between the magnetic layers are coupled to each other.

Read units 130 may be disposed apart from one another in the first horizontal direction X, on the tunnel barrier layer 105 on the upper magnetic track layer 120. In the drawings, four read units (read ports 1, 2, 3, and 4) are illustrated, but the number of read units 130 is not limited thereto. Here, the upper magnetic track layer 120, the tunnel barrier layer 105, and the read unit 130 may be included in a magnetic tunnel junction (MTJ) structure 200. In other words, the read unit 130 may be referred to as an MTJ sensor.

The MTJ structure 200 may include a pinned layer 230, a free layer 220, and a tunnel barrier layer 205 therebetween. A magnetization direction of the pinned layer 230 may be fixed, and a magnetization direction of the free layer 220 may be a parallel or anti-parallel direction with respect to the magnetization direction of the pinned layer 230, based on stored data.

The pinned layer 230 may include a ferromagnetic material. For example, the pinned layer 230 may include a multi-layer thin film or an alloy of a magnetic material (for example, CoFeB, Fe, Co, etc.) and a non-magnetic material (for example, Pt, Ir, Ru, Ta, W, molybdenum (Mo), hafnium (Hf), etc.). In an embodiment, the pinned layer 230 may correspond to the read unit 130.

The tunnel barrier layer 205 may include an oxide of a non-magnetic material or a nitride of a non-magnetic material. For example, the tunnel barrier layer 205 may include one or more materials, such as, but not limited to MgO, TiO, AlO, MgAlO, TiN, VN, and/or BN. In an embodiment, the tunnel barrier layer 205 may correspond to the tunnel barrier layer 105.

The free layer 220 may include a ferromagnetic material, but in an embodiment, the free layer 220 may include Co and Fe and may not include Ni. In an embodiment, the free layer 220 may correspond to the upper magnetic track layer 120.

In some embodiments, when the free layer 220 and the pinned layer 230 of the MTJ structure 200 are in a parallel state, namely, when the MTJ structure 200 has a low resistance, this may be defined as a data 0 (zero) state. On the other hand, when the free layer 220 and the pinned layer 230 of the MTJ structure 200 are in an anti-parallel state, namely, when the MTJ structure 200 has a high resistance, this may be defined as a data 1 (one) state. In other embodiments, when the free layer 220 and the pinned layer 230 of the MTJ structure 200 are in an anti-parallel state, this may be defined as a data 0 state, and when the free layer 220 and the pinned layer 230 of the MTJ structure 200 are in a parallel state, this may be defined as a data 1 state.

The read unit 130 may overlap a corresponding second magnetic domain 120D among a plurality of second magnetic domains 120D of the upper magnetic track layer 120 and a corresponding first magnetic domain 110D among a plurality of first magnetic domains 110D of the lower magnetic track layer 110 in a vertical direction Z. Therefore, in the magnetic memory device 10 according to an embodiment, the read unit 130 may read data, based on a magnetization direction of the upper magnetic track layer 120 copied from the lower magnetic track layer 110.

High-capacity memory devices may be needed for miniaturized, multifunctional, and high-performance electronic products. A racetrack, including a plurality of magnetic domains storing information according to the motion of a domain wall between magnetic domains, has been proposed for providing a high capacity memory device. Also, memory devices of a magnetic domain wall shift register type including a racetrack have been developed. It is generally desirable to implement magnetic memory devices with a stable motion of a magnetic domain wall, a high degree of integration, and desired long lifetime.

Generally, a magnetic memory device may read a recorded magnetization direction through an MTJ structure. However, in a memory device of a magnetic domain wall shift register type, when a high voltage is applied to both ends of a magnetic track layer for the motion of a domain, the high voltage may be applied to an MTJ structure together, and thus, a problem where a tunnel barrier layer is broken down may occur.

To solve or mitigate such a problem, the magnetic memory device 10 according to an embodiment may have a structure where the spacer layer 103 including an insulating material is disposed between the lower magnetic track layer 110 and the upper magnetic track layer 120 to electrically disconnect the upper magnetic track layer 120 of the MTJ structure 200 from the lower magnetic track layer 110 driven with a high voltage.

The motion of a magnetization direction of the first magnetic domain 110D of the lower magnetic track layer 110 disposed at a relatively lower side may be copied to the second magnetic domain 120D of the upper magnetic track layer 120 disposed at a relatively upper side, based on a leakage magnetic field. Based on a method of reading copied magnetic information through the MTJ structure 200, the magnetic memory device 10 may operate.

As a result, in the magnetic memory device 10 according to an embodiment, because it is not needed to apply a high voltage to the upper magnetic track layer 120, a problem may be solved where the high voltage is applied to the tunnel barrier layer 105, and due to this, the tunnel barrier layer 105 is broken down by the accumulation of fatigue. That is, in the magnetic memory device 10 according to an embodiment, the MTJ structure 200 may theoretically perform a read operation infinite times.

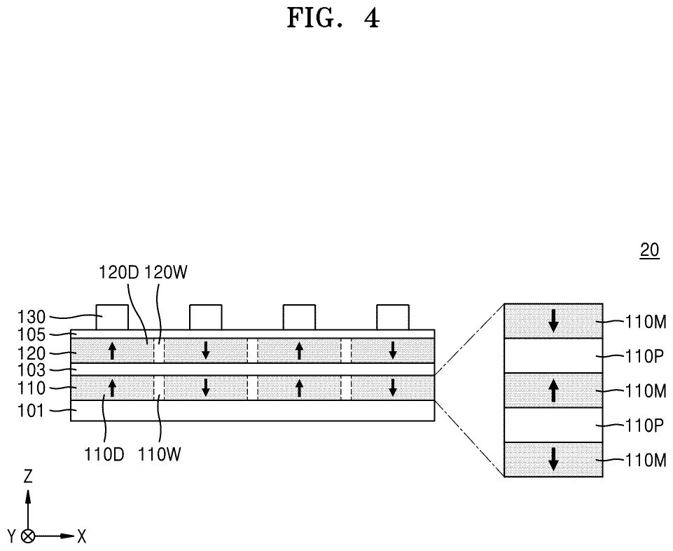

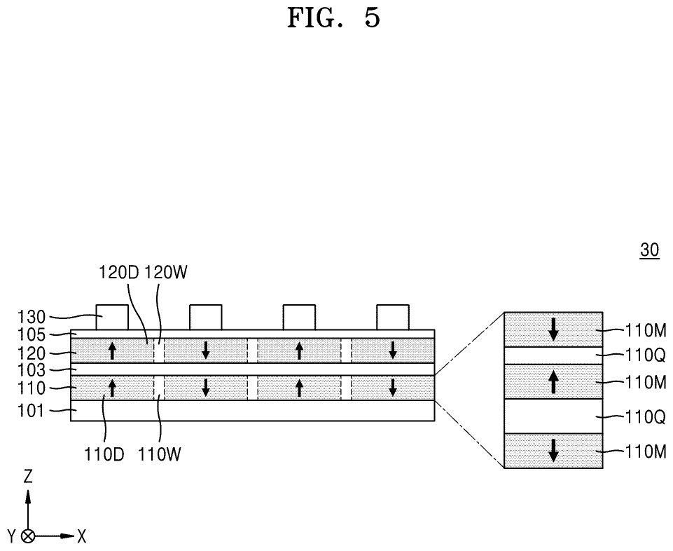

FIGS. 4 and 5 are cross-sectional views illustrating elements of a magnetic memory device according to further embodiments.

Materials used for implementing one or more of the elements of magnetic memory devices 20 and 30 described below may be substantially the same as or similar to the descriptions of FIGS. 1 to 3. Therefore, for convenience of description, a difference with the magnetic memory device 10 described above will be mainly described below.

Referring to FIG. 4, a magnetic memory device 20 according to an embodiment may include a conductive layer 101, a lower magnetic track layer 110 disposed on the conductive layer 101, a spacer layer 103 disposed on the lower magnetic track layer 110, an upper magnetic track layer 120 disposed on the spacer layer 103, a tunnel barrier layer 105 disposed on the upper magnetic track layer 120, and a plurality of read units 130 disposed on the tunnel barrier layer 105.

In the magnetic memory device 20 according to an embodiment, the lower magnetic track layer 110 may include 2N+1 (where N may be a natural number) number of first magnetic layers 110M and 2N number of first coupling layers 110P disposed between the first magnetic layers 110M. For example, the first magnetic layers 110M may each include Co and Ni, and the first coupling layers 110P may each include Ru or Ir. By adjusting a thickness of the first coupling layers 110P, a relationship between the first magnetic layers 110M may be adjusted to be ferromagnetic or anti-ferromagnetic.

In the magnetic memory device 20 according to an embodiment, the upper magnetic track layer 120 may include at least one second magnetic layer (not shown) including a material which differs from a material of each of the first magnetic layers 110M included in the lower magnetic track layer 110. For example, the at least one second magnetic layer may include Co and/or Fe.

In the magnetic memory device 20 according to an embodiment configured as described above, the lower magnetic track layer 110 may be configured with an odd number of first magnetic layers 110M, and thus, a stray field, which is a leakage magnetic field, may be formed in the lower magnetic track layer 110. Such a leakage magnetic field may affect a magnetization direction of the upper magnetic track layer 120, and thus, a magnetization direction of the lower magnetic track layer 110 may be parallel to the magnetization direction of the upper magnetic track layer 120.

Referring to FIG. 5, a magnetic memory device 30 according to an embodiment may include a conductive layer 101, a lower magnetic track layer 110 disposed on the conductive layer 101, a spacer layer 103 disposed on the lower magnetic track layer 110, an upper magnetic track layer 120 disposed on the spacer layer 103, a tunnel barrier layer 105 disposed on the upper magnetic track layer 120, and a plurality of read units 130 disposed on the tunnel barrier layer 105.

In the magnetic memory device 30 according to an embodiment, the lower magnetic track layer 110 may include 2N+1 (where N may be a natural number) number of first magnetic layers 110M and 2N number of first coupling layers 110Q disposed between the first magnetic layers 110M. For example, the first magnetic layers 110M may each include Co and/or Ni, and the first coupling layers 110Q may each include Ru or Ir. Here, at least one first coupling layer 110Q of the first coupling layers 110Q may have a thickness that differs from a thickness of each of the other first coupling layers 110Q. For example, as illustrated, a thickness of a first coupling layer 110Q of an upper layer may be less than that of a first coupling layer 110Q of a lower layer. In detail, a thickness of the first coupling layer 110Q of the upper layer may be about 0.4 nm and a thickness of the first coupling layer 110Q of the lower layer may be about 0.9 nm, but embodiments of the inventive concept are not limited thereto.

In the magnetic memory device 30 according to an embodiment, the upper magnetic track layer 120 may include at least one second magnetic layer (not shown) including a material that differs from a material of each of the first magnetic layers 110M included in the lower magnetic track layer 110. For example, the at least one second magnetic layer may include Co and/or Fe.

In the magnetic memory device 30 according to an embodiment configured as described above, the lower magnetic track layer 110 may be configured with an odd number of first magnetic layers 110M, and thus, a stray field, which is a leakage magnetic field, may be formed in the lower magnetic track layer 110. Such a leakage magnetic field may affect a magnetization direction of the upper magnetic track layer 120, and thus, a magnetization direction of the lower magnetic track layer 110 may be parallel to the magnetization direction of the upper magnetic track layer 120.

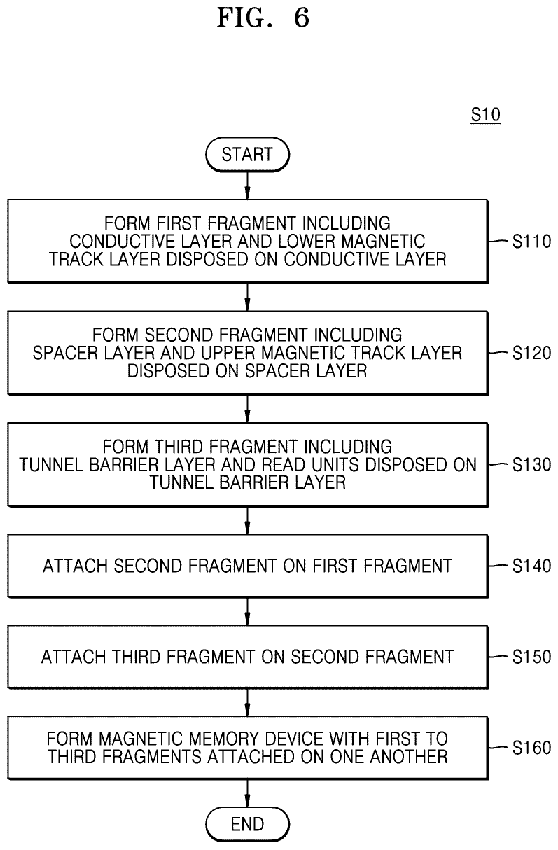

FIG. 6 is a flowchart illustrating a method S10 of manufacturing a magnetic memory device, according to an embodiment.

Referring to FIG. 6, the method S10 of manufacturing the magnetic memory device may include a process sequence of first to sixth operations S110 to S160.

In a case where some embodiments may be differently implemented, a certain process sequence may, for example, be performed differently than a described sequence. For example, two processes, which are continuously described, may be substantially simultaneously performed, or may be performed in a sequence opposite to a described sequence.

The method S10 of manufacturing the magnetic memory device according to an embodiment may include a first operation S110 of forming a first fragment including a conductive layer and a lower magnetic track layer disposed on the conductive layer, a second operation S120 of forming a second fragment including a spacer layer and an upper magnetic track layer disposed on the spacer layer, a third operation S130 of forming a third fragment including a tunnel barrier layer and a plurality of read units disposed on the tunnel barrier layer, a fourth operation S140 of attaching the second fragment on the first fragment, a fifth operation S150 of attaching the third fragment on the second fragment, and a sixth operation S160 of forming a magnetic memory device with the first to third fragments attached on one another.

However, the method S10 of manufacturing the magnetic memory device is not limited thereto. In other embodiments, a magnetic memory device may not be formed with first to third fragments, and one stack structure may be formed and the magnetic memory device may be manufactured by using a photolithography process and an etching process.

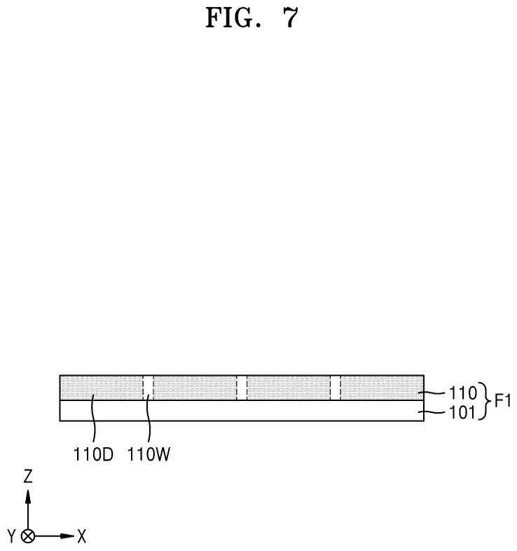

Example technical features of each of the first to sixth operations S110 to S160 will be described below in detail with reference to FIGS. 7 to 9.

FIGS. 7 to 9 are cross-sectional views illustrating a method of manufacturing a magnetic memory device in process sequence, according to some embodiments.

Referring to FIG. 7, a first fragment F1 including a conductive layer 101 and a lower magnetic track layer 110 disposed on the conductive layer 101 may be formed.

The conductive layer 101 and the lower magnetic track layer 110 may be sequentially formed on a first base substrate (not shown). In some embodiments, a mask pattern (not shown) may be formed on the lower magnetic track layer 110, and the first fragment F1 may be formed by sequentially etching the lower magnetic track layer 110 and the conductive layer 101 by using the mask pattern as an etch mask.

The conductive layer 101 may include Ir, Ru, Ta, Pt, Pd, Bi, Ti, and/or W, but embodiments are not limited thereto.

The lower magnetic track layer 110 may include first magnetic domains 110D and first magnetic domain walls 110W each provided between two adjacent first magnetic domains 110D of the first magnetic domains 110D, which are arranged in a first horizontal direction X. Also, the lower magnetic track layer 110 may include Co and/or Ni and may not include Fe.

The conductive layer 101 and the lower magnetic track layer 110 may each be formed by using a chemical vapor deposition (CVD) process, a physical vapor deposition (PVD) process, or an atomic layer deposition (ALD) process.

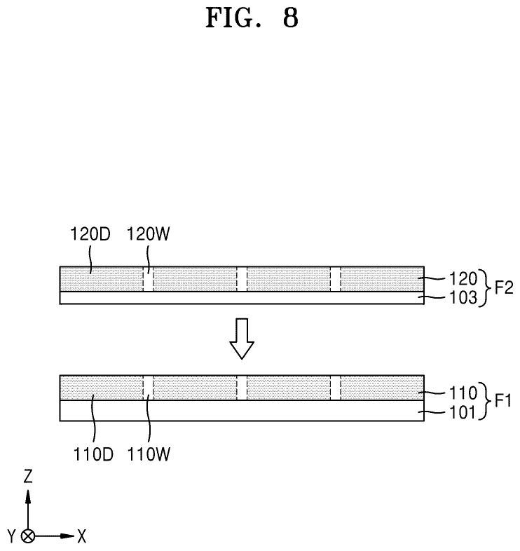

Referring to FIG. 8, a second fragment F2 including a spacer layer 103 and an upper magnetic track layer 120 disposed on the spacer layer 103 may be formed.

The spacer layer 103 and the upper magnetic track layer 120 may be sequentially formed on a second base substrate (not shown). In some embodiments, a mask pattern (not shown) may be formed on the upper magnetic track layer 120, and the second fragment F2 may be formed by sequentially etching the upper magnetic track layer 120 and the spacer layer 103 by using the mask pattern as an etch mask.

The spacer layer 103 may include an insulating material, and for example, may include one or more materials, such as h-BN, aluminum oxide, silicon oxide, silicon nitride, silicon oxynitride, and/or graphene.

Also, h-BN may have a two-dimensional (2D) sheet structure including a B atom and an N atom each having a hexagonal lattice structure, and moreover, a multi-layer 2D sheet structure may be stacked, whereby h-BN may be included in a three-dimensional (3D) structure. Therefore, the second fragment F2 may be formed through the spacer layer 103 including h-BN.

The upper magnetic track layer 120 may include second magnetic domains 120D and second magnetic domain walls 120W each provided between two adjacent second magnetic domains 120D of the second magnetic domains 120D, which are arranged in the first horizontal direction X. Also, the upper magnetic track layer 120 may include Co and/or Fe and may not include Ni. That is, a magnetic element included in the lower magnetic track layer 110 may differ from a magnetic element included in the upper magnetic track layer 120.

Each of the spacer layer 103 and the upper magnetic track layer 120 may be formed by using a CVD process, a PVD process, or an ALD process.

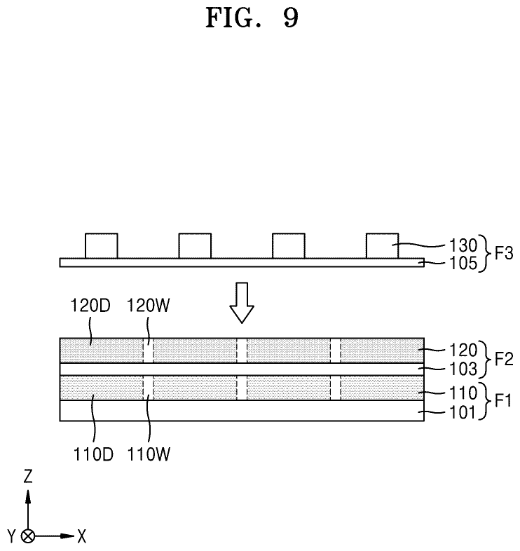

In some embodiments, the second fragment F2 may be attached on the first fragment F1. In more detail, the second fragment F2 may be formed, and the second fragment F2 may be detached from the second base substrate by using an adhesive stamp and may be attached to the first fragment F1. In other embodiments, the attachment of the second fragment F2 may be performed after a third fragment F3 (see FIG. 9) is formed.

Referring to FIG. 9, the third fragment F3 including a tunnel barrier layer 105 and a plurality of read units 130 disposed on the tunnel barrier layer 105 may be formed.

The tunnel barrier layer 105 and the plurality of read units 130 may be sequentially formed on a third base substrate (not shown). In some embodiments, a mask pattern (not shown) may be formed on a material layer where the plurality of read units 130 are to be formed, and the third fragment F3 may be formed by sequentially etching the material layer and the tunnel barrier layer 105 by using the mask pattern as an etch mask.

The tunnel barrier layer 105 may include an oxide of a non-magnetic material or a nitride of a non-magnetic material. For example, the tunnel barrier layer 105 may include one or more materials, such as MgO, TiO, AlO, MgAlO, TiN, VN, and/or BN.

The plurality of read units 130 may include a ferromagnetic material. For example, the plurality of read units 130 may include a multi-layer thin film or an alloy of a magnetic material (for example, CoFeB, Fe, Co, etc.) and a non-magnetic material (for example, Pt, Ir, Ru, Ta, W, Mo, Hf, etc.).

Each of the tunnel barrier layer 105 and the plurality of read units 130 may be formed by using a CVD process, a PVD process, or an ALD process.

In some embodiments, the third fragment F3 may be attached to the second fragment F2. In more detail, the third fragment F3 may be formed, and the third fragment F3 may be detached from the third base substrate by using an adhesive stamp and may be attached to the second fragment F2.

Based on the manufacturing method described above, the magnetic memory device 10 (see FIG. 1) according to an embodiment may be manufactured. However, the method S10 of manufacturing the magnetic memory device is not limited thereto. In other embodiments, for example, a magnetic memory device may not be formed with first to third fragments, and one stack structure may be formed and the magnetic memory device may be manufactured by using a photolithography process and an etching process.

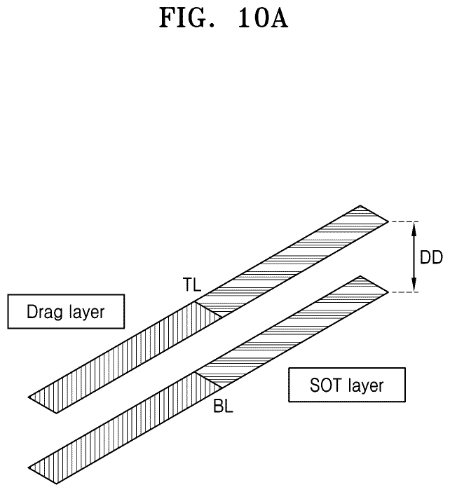

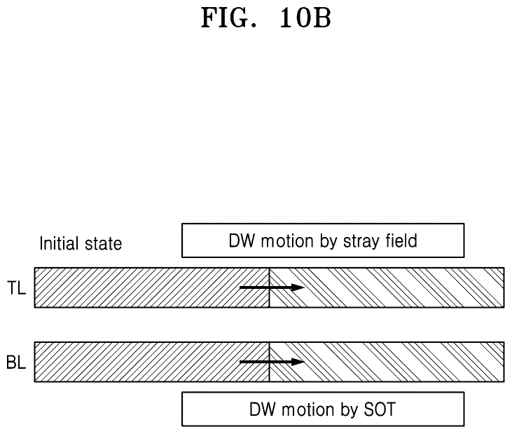

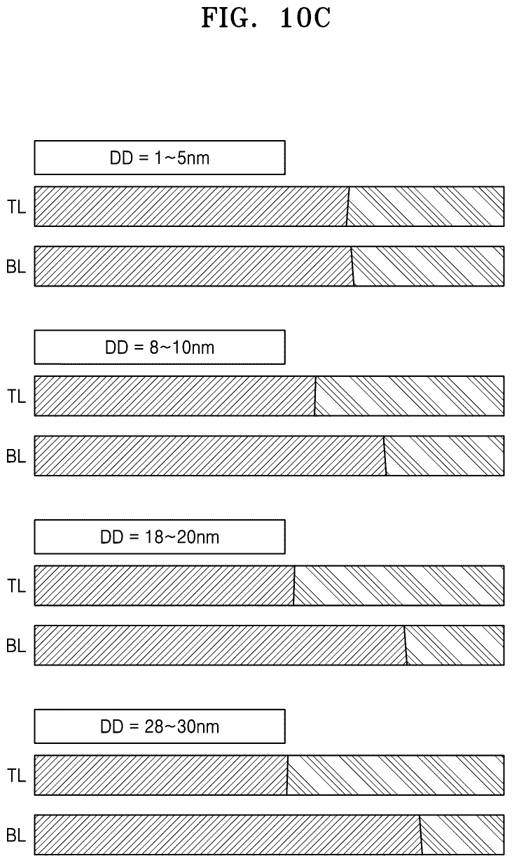

FIGS. 10A to 10C are diagrams illustrating a magnetic copy feature of a magnetic memory device according to some embodiments.

Referring to FIGS. 10A to 10C, a state where a magnetization direction of a lower magnetic track layer BL may be copied to a magnetization direction of an upper magnetic track layer TL will be described below.

An SOT layer, which allows an SOT to be generated with a current flowing in, may be disposed under the lower magnetic track layer BL. Also, a drag layer may be disposed on the upper magnetic track layer TL.

The lower magnetic track layer BL and the upper magnetic track layer TL may be disposed to have a first interval DD therebetween. In this case, based on a magnitude of the first interval DD, an experiment on the degree to which the motion of a magnetic domain wall (DW) by the SOT in the lower magnetic track layer BL affects the motion of a magnetic domain wall by a stray field in the upper magnetic track layer TL has been performed.

Here, the first interval DD may be set by adjusting a thickness of the spacer layer 103 (see FIG. 1) described above. However, embodiments are not limited thereto.

When the first interval DD is about 1 nm to about 5 nm, it may be seen that the motion of the magnetic domain wall of the lower magnetic track layer BL is substantially the same as the motion of the magnetic domain wall of the upper magnetic track layer TL.

Also, when the first interval DD is configured to be about 8 nm to about 10 nm, it may be seen that a difference between the motion of the magnetic domain wall of the lower magnetic track layer BL and the motion of the magnetic domain wall of the upper magnetic track layer TL occurs.

Also, when the first interval DD is configured to be about 18 nm to about 20 nm, it may be seen that a large difference between the motion of the magnetic domain wall of the lower magnetic track layer BL and the motion of the magnetic domain wall of the upper magnetic track layer TL occurs.

Also, when the first interval DD is configured to be about 28 nm to about 30 nm, it may be seen that a larger difference between the motion of the magnetic domain wall of the lower magnetic track layer BL and the motion of the magnetic domain wall of the upper magnetic track layer TL occurs.

That is, when the first interval DD is about 1 nm to about 5 nm, a magnetization direction of the lower magnetic track layer BL may be copied to be substantially equal to a magnetization direction of the upper magnetic track layer TL. On the other hand, when the first interval DD is greater than about 5 nm, it has been experimentally confirmed that a magnetization direction difference between the lower magnetic track layer BL and the upper magnetic track layer TL occurs. Also, it may be difficult to form the first interval DD to a thickness which is less than about 1 nm, and it may be difficult to implement a magnetic characteristic with respect to a fine thickness.

Therefore, referring again to FIG. 1, because a thickness of the spacer layer 103 is about 1 nm to about 5 nm, the motion of a magnetization direction of the first magnetic domain 110D of the lower magnetic track layer 110 disposed at a relatively lower side may be copied to be substantially equal to the motion of a magnetization direction of the second magnetic domain 120D of the upper magnetic track layer 120 disposed at a relatively upper side based on a leakage magnetic field. Based on a method of reading copied magnetic information through the MTJ structure 200, the magnetic memory device 10 may operate.

Hereinabove, example embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A magnetic memory device comprising:
a lower magnetic track layer extending in a first direction and including a plurality of first magnetic domains;
a spacer layer on the lower magnetic track layer and extending in the first direction;
an upper magnetic track layer on the spacer layer and extending in the first direction, the upper magnetic track layer including a plurality of second magnetic domains; and
a plurality of read units on the upper magnetic track layer and arranged apart from one another in the first direction,
wherein the plurality of first magnetic domains and the plurality of second magnetic domains have magnetization directions parallel to each other at positions overlapping each other in a second direction perpendicular to the first direction.

2. The magnetic memory device of claim 1, wherein a magnetization direction of the upper magnetic track layer is equal to a magnetization direction of the lower magnetic track layer based on a leakage magnetic field of the lower magnetic track layer, such that the magnetization direction of the upper magnetic track layer and the magnetization direction of the lower magnetic track layer are formed in parallel to each other.

3. The magnetic memory device of claim 2, wherein each of the plurality of read units is a pinned layer of a magnetic tunnel junction structure,
wherein the upper magnetic track layer is a free layer of the magnetic tunnel junction structure, and
wherein each of the plurality of read units is configured to read a magnetization direction of the upper magnetic track layer.

4. The magnetic memory device of claim 2, wherein the lower magnetic track layer comprises:
2N+1 (where N is a natural number) number of first magnetic layers; and
2N number of coupling layers between the 2N+1 number of first magnetic layers.

5. The magnetic memory device of claim 4, wherein each of the 2N+1 number of first magnetic layers comprises cobalt (Co) and nickel (Ni), and
wherein each of the 2N number of coupling layers comprises ruthenium (Ru) or iridium (Ir).

6. The magnetic memory device of claim 5, wherein at least one of the 2N number of coupling layers has a thickness that differs from a thickness of each of other ones of the 2N number of coupling layers.

7. The magnetic memory device of claim 4, wherein the upper magnetic track layer comprises at least one second magnetic layer including a material that differs from a material of each of the 2N+1 number of first magnetic layers.

8. The magnetic memory device of claim 7, wherein the at least one second magnetic layer comprises cobalt (Co) and iron (Fe).

9. The magnetic memory device of claim 1, wherein the spacer layer comprises hexagonal boron nitride (h-BN), and
wherein a thickness of the spacer layer is about 1 nm to about 5 nm.

10. The magnetic memory device of claim 1, further comprising a conductive layer under the lower magnetic track layer and extending in the first direction,
wherein a length of the conductive layer, a length of the lower magnetic track layer, a length of the spacer layer, and a length of the upper magnetic track layer are equal to one another in the first direction.

11. A magnetic memory device comprising:
a spin hall conductive layer;
an operation magnetic track layer and a copy magnetic track layer, stacked in a first direction on the spin hall conductive layer;
a spacer layer between the operation magnetic track layer and the copy magnetic track layer;
a tunnel barrier layer on the copy magnetic track layer; and
a plurality of magnetic tunnel junction sensors on the tunnel barrier layer,
wherein the operation magnetic track layer and the copy magnetic track layer have magnetization directions parallel to each other at positions overlapping each other in the first direction based on a leakage magnetic field of the operation magnetic track layer.

12. The magnetic memory device of claim 11, wherein the operation magnetic track layer comprises an odd number of first magnetic layers that are configured to generate the leakage magnetic field.

13. The magnetic memory device of claim 12, wherein the copy magnetic track layer comprises at least one second magnetic layer including a material that differs from a material of each of the first magnetic layers.

14. The magnetic memory device of claim 11, wherein the operation magnetic track layer comprises a plurality of first magnetic domains and a plurality of first magnetic domain walls arranged alternately in a second direction perpendicular to the first direction,
wherein the copy magnetic track layer comprises a plurality of second magnetic domains and a plurality of second magnetic domain walls arranged alternately in the second direction, and
wherein the plurality of first magnetic domains and the plurality of second magnetic domains have magnetization directions parallel to each other at positions overlapping each other in the first direction.

15. The magnetic memory device of claim 11, wherein the spin hall conductive layer comprises a spin orbit torque (SOT) induction layer.

16. A magnetic memory device comprising:
a lower magnetic track layer including a plurality of first magnetic domains and a plurality of first magnetic domain walls alternately arranged and extending in a first direction;
a spacer layer on the lower magnetic track layer and extending in the first direction, the spacer layer having a thickness of about 1 nm to about 5 nm;
an upper magnetic track layer including a plurality of second magnetic domains and a plurality of second magnetic domain walls alternately arranged and extending in the first direction, the upper magnetic track layer being on the spacer layer; and
a plurality of read units on the upper magnetic track layer, the plurality of read units being configured to read a magnetization direction of the upper magnetic track layer and being arranged apart from one another in the first direction,
wherein the plurality of first magnetic domain walls and the plurality of second magnetic domain walls overlap each other in a second direction perpendicular to the first direction, and
wherein the plurality of first magnetic domains and the plurality of second magnetic domains have magnetization directions parallel to each other at positions overlapping each other in the second direction.

17. The magnetic memory device of claim 16, wherein the lower magnetic track layer and the upper magnetic track layer have magnetization directions parallel to each other at positions overlapping each other in the second direction based on a leakage magnetic field of the lower magnetic track layer.

18. The magnetic memory device of claim 17, wherein the lower magnetic track layer comprises a plurality of first magnetic layers and a plurality of coupling layers between the plurality of first magnetic layers, which are configured to generate the leakage magnetic field.

19. The magnetic memory device of claim 18, wherein the upper magnetic track layer comprises at least one second magnetic layer including a material that differs from a material of each of the plurality of first magnetic layers.

20. The magnetic memory device of claim 19, wherein each of the plurality of first magnetic layers comprises cobalt (Co) and nickel (Ni), and
wherein the at least one second magnetic layer comprises cobalt (Co) and iron (Fe).
